(19) United States
(12) Patent Application Publication
(10) Pub. No.: US 2006/0145228 A1
(43) Pub. Date: Jul. 6, 2006

(54) Semiconductor device

(76) Inventors: Masaru Kito, Yokohama-shi (JP); Ryota Katsumata, Yokohama-shi (JP); Hideaki Aochi, Kawasaki-shi (JP); Nobutoshi Aoki, Yokohama-shi (JP); Masaki Kondo, Kawasaki-shi (JP); Sanae Ito, Yokohama-shi (JP)

Correspondence Address: OBLON, SPIVAK, MCCLELLAND, MAIER & NEUSTADT, P.C., 1940 DUKE STREET, ALEXANDRIA, VA, 22314, US

(21) Appl. No.: 11/311,268

(22) Filed: Dec. 20, 2005

(30) Foreign Application Priority Data
Jan. 6, 2005 (JP) 2005-001883

(51) Int. Cl. H01L 29/94

(52) U.S. Cl. 257/301

(57) ABSTRACT

A semiconductor memory device comprising a semiconductor substrate, element isolating regions formed on the semiconductor substrate, an element forming region provided between the element isolating regions on the semiconductor substrate, the element forming region having a protruding portion, a transistor having a channel formed in the protruding portion of the element forming region, and a capacitor formed in or on the semiconductor substrate to be connected to the transistor, wherein the protruding portion in the element forming region includes first and second inclined and opposed planes arranged along a channel width direction of the transistor, and an upper plane provided between the first and second inclined planes.

### CROSS-REFERENCE TO RELATED APPLICATIONS

This application is based upon and claims the benefit of priority from prior Japanese Patent Application No. 2005-001883, filed Jan. 6, 2005, the entire contents of which are incorporated herein by reference.

### BACKGROUND OF THE INVENTION

1. Field of the Invention

The present invention relates to a semiconductor device such as a DRAM having memory cells each formed by combining a transistor and a capacitor.

2. Description of the Related Art

It is necessary to miniaturize transistors and capacitors forming memory cells for increasing a memory capacity of the DRAM. However, when the transistors and the capacitors are miniaturized, the drivability of the transistors or amounts of drain currents of the transistors are decreased. Particularly, it is necessary to increase the drivability of the transistors for increasing the operation speed of the DRAM. However, it is very difficult to miniaturize the transistors while maintaining or increasing the drivability of the transistors.

Jpn. J. Appl. Phys. Vol. 42 (2003) pp. 1865-1869, “Performance of DRAM Cell Transistor with Thermal Desorption Silicon Etching (TDSE) and Selective Si Channel Epi Techniques: Chul-Sung Kim et al.

Conventionally, in order to solve the above-mentioned problems, there is a solution described in a literature:

Jpn. J. Appl. Phys. Vol. 42 (2003) pp. 1865-1869, “Performance of DRAM Cell Transistor with Thermal Desorption Silicon Etching (TDSE) and Selective Si Channel Epi Techniques: Chul-Sung Kim et al.

According to the method described in this literature, an epitaxial silicon layer is formed by a selective epitaxial growth method in an element forming region or an active area (AA) in which a channel of a transistor is formed to have a substantial wide channel width.

However, there is a demand for an improved transistor which is applicable to a memory cell of a high speed and high performance DRAM, and which is superior than the transistor described in the above-mentioned literature.

### BRIEF SUMMARY OF THE INVENTION

One aspect of the present invention provides a semiconductor device comprising:

a semiconductor substrate;

element isolating regions formed on the semiconductor substrate;

an element forming region provided between the element isolating regions on the semiconductor substrate, the element forming region having a protruding portion being a selective epitaxial growth silicon region formed on the semiconductor substrate;

a transistor having a channel formed in the protruding portion of the element forming region; and

a capacitor formed in the semiconductor substrate to configure a memory cell of a DRAM in association with the transistor, wherein

the protruding portion in the element forming region includes first and second inclined and opposed planes arranged along a channel width direction of the transistor, and an upper plane provided between the first and second inclined planes.

Another aspect of the present invention provides a semiconductor device comprising:

a semiconductor substrate;

element isolating regions formed on the semiconductor substrate;

an element forming region provided between the element isolating regions on the semiconductor substrate, the element forming region being an etching-formed region having a protruding portion in the semiconductor substrate;

a transistor having a channel formed in the protruding portion of the element forming region; and a capacitor formed in the semiconductor substrate to configure a memory cell of a DRAM in association with the transistor, wherein

the protruding portion in the element forming region includes first and second inclined and opposed planes arranged along a channel width direction of the transistor, and an upper plane provided between the first and second inclined planes.

A further aspect of the present invention provides a semiconductor device comprising:

a semiconductor substrate;

element isolating regions formed on the semiconductor substrate;

an element forming region provided between the element isolating regions in the semiconductor substrate, the element forming region having a protruding portion formed on the semiconductor substrate;

a transistor having a channel formed in the protruding portion of the element forming region; and

a capacitor formed on the semiconductor substrate to configure a memory cell of a DRAM in association with the transistor, wherein

in the channel width direction of the element forming region, a width of the protruding portion is narrower than a width of the element forming region in the semiconductor substrate.

### BRIEF DESCRIPTION OF THE SEVERAL VIEWS OF THE DRAWING

FIGS. 1A to 1C are sectional views showing a structure of a memory cell section according to a first embodiment of the present invention;

FIGS. 1D and 1E are sectional views showing a structure of a peripheral circuit section according to the first embodiment of the present invention;

FIGS. 2A to 2D are sectional views showing a structure of the memory cell section at steps of a process for manufacturing the memory cell section shown in FIG. 1A;

FIGS. 3A to 3D are sectional views showing a structure of the memory cell section at further steps of the process for manufacturing the memory cell section shown in FIG. 1A;

FIGS. 4A to 4D are sectional views showing a structure of the memory cell section at still further steps of the process for manufacturing the memory cell section shown in FIG. 1A;

FIGS. 5A to 5E, 5G and 5H are sectional views showing a structure of the memory cell section at further steps of the process for manufacturing the memory cell section shown in FIG. 1A;

FIGS. 5F and 5I are sectional views showing a structure of the peripheral circuit section at further steps of the process for manufacturing the peripheral circuit section shown in FIG. 1D;

FIGS. 6A to 6I are sectional views showing a structure of the memory cell section and the peripheral circuit section at still further steps of the process for manufacturing the memory cell section and the peripheral circuit section shown in FIGS. 1A to 1E;

FIGS. 7A to 7I are sectional views showing a structure of the memory cell section at further steps of the process for manufacturing the memory cell section shown in FIGS. 1A to 1C;

FIGS. 8A to 8I are sectional views showing a structure of the memory cell section at further steps of the process for manufacturing the memory cell section shown in FIGS. 1A to 1C;

FIGS. 9A to 9F are sectional views showing a structure of the memory cell section at further steps of the process for manufacturing the memory cell section shown in FIGS. 1A to 1C;

FIGS. 10A to 10C are sectional views showing a structure of the memory cell section at still further steps of the process for manufacturing the memory cell section shown in FIG. 1A to 1C;

FIG. 10D is an enlarged sectional view of a part AA shown in FIG. 10C;

FIG. 10E shows a photographed SEM image of the epitaxial silicon region shown in FIG. 10D;

FIGS. 11A to 11K are sectional views showing a structure of the memory cell section and the peripheral circuit section at several steps of a process for manufacturing the semiconductor memory device according to a second embodiment of the present invention;

FIGS. 12A to 12F are sectional views showing a structure of the memory cell section at further steps of the process for manufacturing the memory cell section according to the second embodiment following the steps shown in FIGS. 11I and 11J;

FIGS. 13A to 13C are sectional views showing a structure of the memory cell section of the second embodiment at further steps of the process following the steps shown in FIGS. 12D to 12F;

FIGS. 14A to 14F are sectional views showing a structure of a memory cell section at steps of a process for manufacturing the semiconductor memory device according to a third embodiment of the present invention;

FIGS. 15A to 15H are sectional views showing a structure of the memory cell section at following steps of the process for manufacturing the memory cell section shown in FIGS. 14E and 14F according to the third embodiment of the present invention;

FIGS. 16A to 16H are sectional views showing a structure of the memory cell section at further steps of the process for manufacturing the memory cell section shown in FIGS. 15G and 15H according to the third embodiment of the present invention;

FIGS. 17A to 17H are sectional views showing a structure of the memory cell section at steps of a process for manufacturing the memory cell section according to a fourth embodiment of the present invention;

FIGS. 18A to 18D are sectional views showing a structure of the memory cell section at further steps of the process for manufacturing the memory cell section according to the fourth embodiment of the present invention;

FIGS. 19A to 19C are views for explaining features of the present invention;

FIG. 19D is a photograph of an SEM image of a manufactured portion according to the AA part shown in FIG. 19C;

FIG. 20 is a graph explaining an S-factor of a transistor manufactured according to the present invention;

FIG. 21 is a graph showing a Vg-Id characteristic of a transistor manufactured according to the present invention;

FIG. 22 is an enlarged view of an epitaxial silicon region formed at an upper portion of an active area (AA);

FIG. 23 is a graph showing a relationship between an upper end width of an epitaxial silicon region and an S-factor; and

FIG. 24 is a graph showing a relationship between a lower width of the epitaxial silicon region and the S-factor.

### DETAILED DESCRIPTION OF THE INVENTION

Embodiments according to the present invention will be described in detail by referring to the accompanying drawing.

### First Embodiment

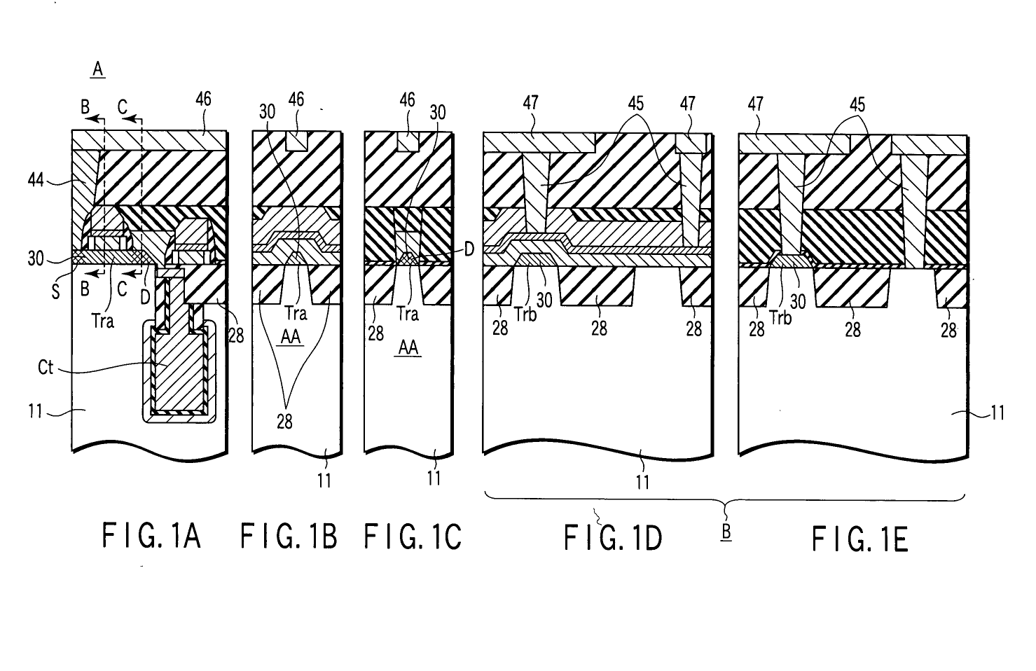

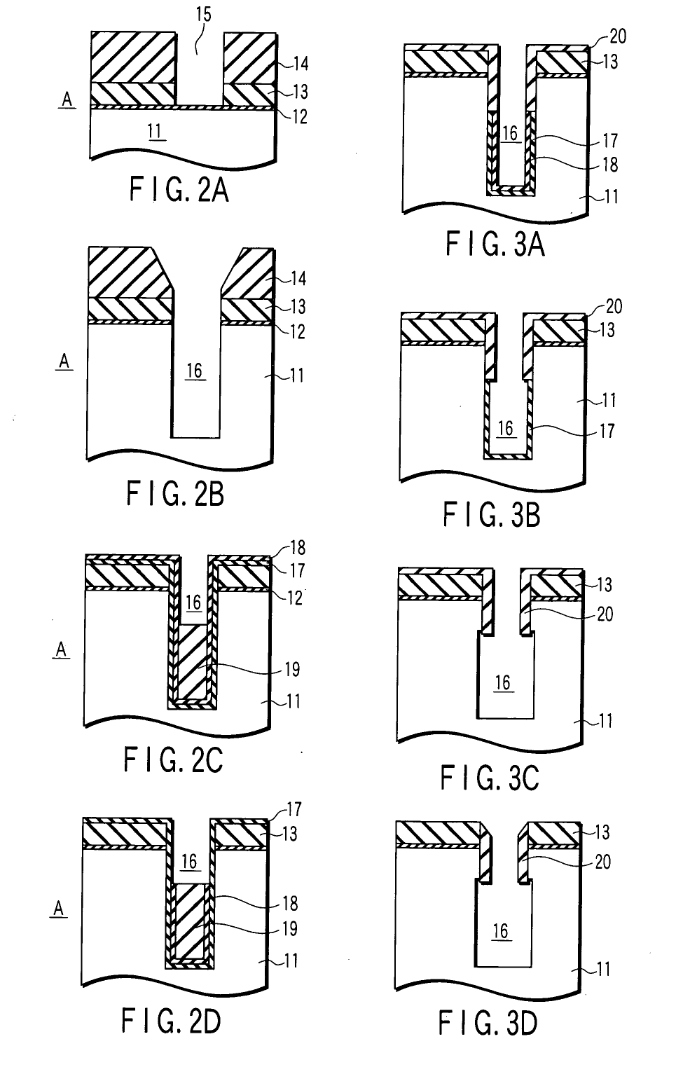

FIGS. 1A to 1E are sectional views showing a structure of a memory cell section and a peripheral circuit section of a DRAM device according to a first embodiment of the present invention. FIG. 1A is a sectional view showing a structure of a capacitor Ct and a memory transistor Tra constituting a memory cell of the DRAM device. FIGS. 1B and 1C are sectional views cut at lines B-B and C-C of FIG. 1A and seen in the direction of the arrows shown therein, respectively. In the following explanation of the embodiments, the memory transistor Tra is formed in an element forming region which is defined as an active area (referred to as AA in the following). The AA includes an area in a silicon substrate 11 between two adjacent element isolation regions 28 and an epitaxial silicon region 30 formed on the area of the silicon substrate 11. As will be described later, a channel region of the transistor Tra is formed in the epitaxial silicon region 30. Steps of the process for manufacturing the DRAM device having a structure shown in FIGS. 1A to 1E will be described in detail by referring to the accompanying drawings of FIGS. 2A to 10E.

For forming a memory section A shown in FIG. 1A, an SiO₂ film 12 of a thickness of 2 nm, an SiN film 13 of a thickness of 200 nm, and a BSG (boron silicate glass) film 14 of a thickness of 1200 nm, for example, are formed one by one on the silicon substrate 11 as shown in FIG. 2A. Then, the whole surface of the silicon substrate 11 is covered with a resist film (not shown) which is then treated in a patterning step using a lithography method to form a resist pattern which is then used for forming a deep trench (hereinafter referred to as DT) in the silicon substrate 11. Thus, the SiN film 13 and BSG film 14 are treated in an etching step using the resist pattern and a DT pattern 15 is formed as shown in FIG. 2A.

Then, the SiO₂ film 12 and the silicon substrate 11 are etched using the BSG film 14 as a mask to form a DT 16 of a depth of 8 μm in the silicon substrate 11 as shown in FIG. 2B.

Then, after the BSG film 14 is removed by a vapor phase decomposition method using vaporized hydrofluoric acid, for example, a sac-aSi (amorphous-silicon) film 17 and SiN film 18 are deposited successively on the whole surface of the silicon substrate 11 including an inner surface of the DT 16, as shown in FIG. 2C. Further, after a resist film is coated, the resist film is so etched back that only a resist film 19 is remained in the DT 16 with a thickness of about 1.3 μm, while the SiN film 18 is partially exposed.

The exposed part of the SiN film 18 is removed to expose the sac-aSi film 17 by a dry etching method such as a CDE method, for example, so that the part of the film 18 covered by the resist film 19 is remained as shown in FIG. 2D. Then, the resist film 19 is removed.

The exposed sac-aSi film 17 is oxidized by means of a thermal oxidizing method to form on the upper portion of the side wall of the DT 16 and upper surface of the SiN film 13 a SiO₂ film 20 with a thickness of 45 nm, for example, as a color oxidation film, as shown in FIG. 3A. Since the lower part of the sac-aSi film 17 in the DT 16 is covered by the SiN barrier film 18, the lower part of the sac-aSi film 17 is not oxidized.

Then, the exposed SiN barrier film 18 is removed by etching using a CDE method or an appropriate method such as a wet etching method to expose the sac-aSi film 17 as shown in FIG. 3B. The etching of the SiN barrier film 18 is performed under a condition that the selective etching ratio of the SiN barrier film 18 with respect to the oxide film 20 is sufficiently large. Therefore, the reduction of the film thickness of the upper collar oxide film 20 during the etching of the film 18 may be suppressed at the minimum level.

Further, the sac-aSi film 17 exposed at bottom portion of the DT 16 is removed by using an etching method such as a CDE method as shown in FIG. 3C. When the sac-aSi film 17 is removed, the inner wall of the DT 16 is exposed. The total area of this inner wall of the DT 16 corresponds to an area of one electrode of a capacitor formed in the DT 16. However, as shown in FIG. 3C, if the inner wall of the DT 16 is over-etched into the substrate 11 behind the level of the back surface of the oxide film 20, the total area of the inner wall of the DT 16 will be increased and an opposing area of the electrode of the capacitor or the capacity of this capacitor formed in this DT 16 will also be increased.

Then, as shown in FIG. 3D, a portion of the collar oxide film 20 deposited above the SiN film 13 is removed by using an anisotropic etching such as an RIE method to remain only a portion of the collar oxide film 20 deposited at an upper inner wall portion of the DT 16.

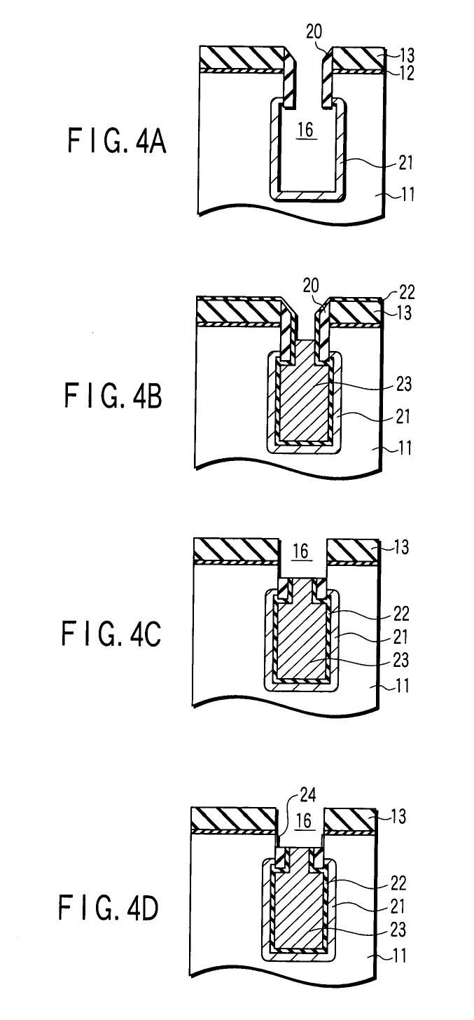

Then, the wafer processed in the step of FIG. 3D is exposed into a vapor phase atmosphere of PH3 at a high temperature of about 900° C. to diffuse phosphor P into the exposed surface of the silicon substrate 11 in the lower part of the DT 16. As a result, as shown in FIG. 4A, a high intensity n+ diffusion layer 21 is formed as one electrode of the capacitor. This diffusion layer 21 is called as a buried electrode. Arsenic As may also be diffused into the silicon substrate 11 by using an AsH3 vapor phase atmosphere, for example, as an impurity other than the phosphor P.

Then, as shown in FIG. 4B, an NO film 22 is deposited as a capacitor dielectric film on the whole surface of the silicon substrate 11 including the inner wall of the DT 16 so that the deposited film 22 contacts with the diffusion layer 21 which acts as the one buried electrode of the capacitor. Further, aSi layer including an impurity As is deposited on the surface of the substrate 11 including the inner surface of the DT 16 to a thickness of about 300 nm. The aSi layer is then etched back by the RIE method, for example, to form a storage node 23 of a thickness of about 60 nm in the DT 16 as the other electrode of the capacitor. As a result, the upper surface of the storage node 23 reaches at a position corresponding to about a half length of the collar oxide film 20. The impurity doped in the aSi layer forming the storage node 23 may be selected from any of n-type impurities other than As.

Then, as shown in FIG. 4C, the upper portion of the NO film 22 is etched off until the edge thereof reaches at a position corresponding to an upper edge of the storage node 23. Then, the collar oxide film 20 is similarly etched off. As a result, as shown in FIG. 4C, a portion of the silicon substrate 11 is exposed at an upper side wall portion of the DT 16.

The silicon substrate including the surface area of the silicon substrate 11 exposed in the DT 16 is put at a nitrogen atmosphere so that the surface area silicon is nitrified to form a thin SiN film 24 of about 5 nm. This SiN film 24 may be formed at the upper side wall of the DT 16 by a different method in which a SiN film is first deposited on a whole surface of the substrate 11, then the deposited SiN film is so etched away that a thin SiN film 24 is remained at only the upper side wall of the DT 16 as shown in FIG. 4D.

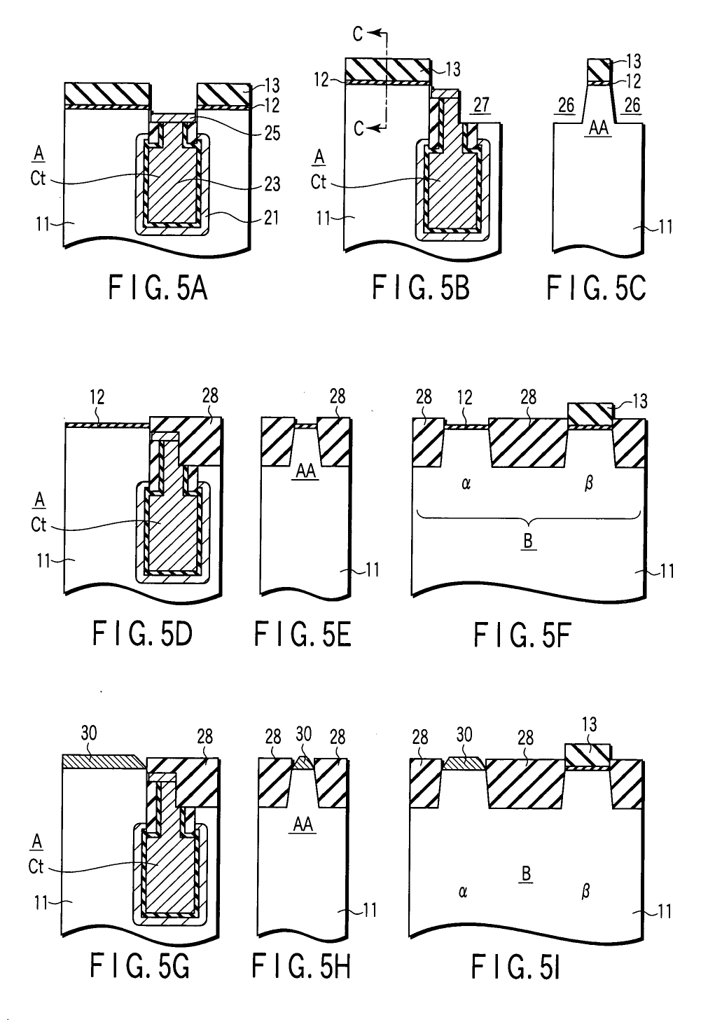

Then, aSi layer doped with As is deposited at a whole surface of the silicon substrate 11 with a thickness of about 200 nm which is then etched back so that an n+ type aSi layer 25 of about 20 nm is buried at a surface area of the silicon substrate 11 in the DT 16 as a conductive layer connected to the storage node 23 of the capacitor, as shown in FIG. 5A. Thus, a trench capacitor Ct functioning as an element composing a memory cell is formed at the memory section A of the DRAM.

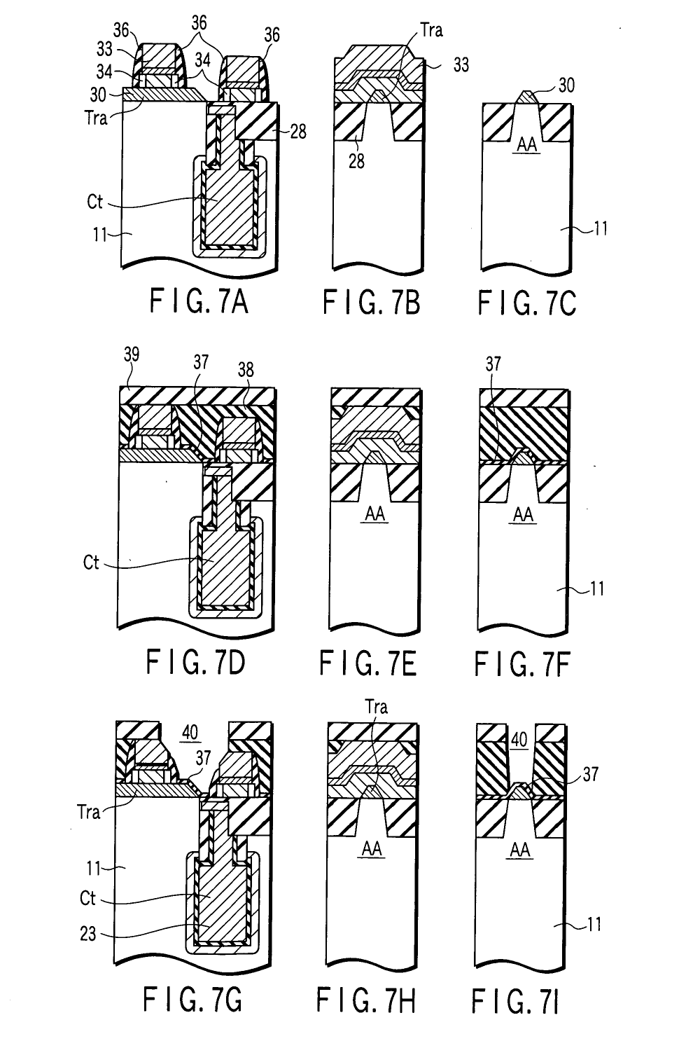

A transistor Tra (see FIG. 7A) used as another constituent of the DRAM memory cell is also formed in the active area AA together with the above-mentioned trench capacitor Ct. In order to form the area AA, a lithography method is applied to the silicon substrate 11 shown in FIG. 5A and a resist pattern corresponding to the area AA pattern. When the SiN film 13 and the SiO₂ film 12 are processed in an etching step using the resist pattern as a mask, STI grooves 26 to be used as element isolation regions between which the area AA is defined are formed as shown in FIG. 5C. The longitudinal direction of the STI groove 26 is set along the plane of FIG. 5B and a sectional structure cut and viewed in the arrow direction C-C in FIG. 5B is shown in FIG. 5C. A part of the upper portion of the capacitor Ct is cut away by the STI groove 27 which is formed in a direction perpendicular to the STI groove 26 as shown in FIG. 5B.

The surface of the silicon substrate 11 exposed in the STI grooves 26, 27 is oxidized in a thermal oxidation step to form an oxide film of about 10 nm (not shown). The whole surface of the silicon substrate 11 including the STI grooves 26, 27 is covered with an STI oxide film deposited by using an HDP (High Density Plasma) method, for example. This deposited STI oxide film is polished by a CMP method to flatten until it is as high as the upper surface of the SiN film 13. The STI film is then etched back by means of wet etching step until the surface of the STI film reaches as high as 30 nm from the surface of the silicon substrate 11. Then, the SiN film 13 remained on the silicon substrate 11 is removed by an etching step to expose the SiO₂ film 12. Thus, the element isolation regions 28 filled with the STI films are formed as shown in FIGS. 5D, 5E and 5F.

FIGS. 5D and 5E show a memory section A including a capacitor and a transistor composing a memory cell of a DRAM formed on an area of the silicon substrate 11 which has another area formed of a periphery circuit section B as shown in FIG. 5F. The periphery circuit section B is formed at the same time when the memory section A is formed on the silicon substrate 11.

At that time, in the same way as in the memory cell section A shown in FIGS. 5D and 5E, the SiN film may be removed as an α section of the peripheral circuit section B shown in FIG. 5F, or the SiN film 13 may be, not removed, but made to remain by forming a resist mask as shown in a β section in FIG. 5F. Because the SiN film 13 can be selectively made to remain by using the resist mask, the device can be configured such that the α section and the β section are mixed in the peripheral circuit section B. Thereafter, the SiO₂ film 12 remaining on the silicon substrate 11 is removed by etching.

Here, before the epitaxial silicon region 30 is formed in the following process, boron B may be implanted with energy of, for example, 10 KeV in the dose of 1.0E-13 into the surface region of the silicon substrate 11. The boron B is then activated by annealing so that the doped boron ions may act as a punch through stopper of the transistor to be formed. Ion implantation for the punch through stopper can also be carried out at an ion implantation process for forming transistor after forming the region 30. However, ions can be implanted at a low acceleration by being implanted in advance, and there is the advantage that the controllability of the process can be expected.

Next, a convex (ridge-like) epitaxial silicon region 30 is formed by a selective epitaxial growth method (hereinafter, called an SEG method) on the surface of the silicon substrate 11 as shown in FIGS. 5G, 5H, and 5I. At this time, inclined planes are formed at the side faces of the protrusion of the ridge-like epitaxial silicon region 30 by surface orientation of the silicon crystal. Note that the epitaxial silicon region 30 is formed on, not only the upper surface of the area AA, but also the entire surface of the silicon substrate 11 exposed by removing the SiN film 13 and the SiO₂ film 12. Accordingly, the epitaxial silicon region 30 is not formed only on the portion of the SiN film 13 remaining on the P section in FIG. 5F. In the case of the present embodiment, the STI regions are formed by filling the STI oxide films 28 before the epitaxial silicon region 30 is formed. Thus, the insulation performance between the storage node of the trench capacitor Ct already formed and the epitaxial silicon region 30 formed later can be ensured without problems.

After the epitaxial silicon region 30 is formed by the SEG method, the SiN film 13 remaining on the β section as shown in FIG. 5F is removed, and the surface of the epitaxial silicon region 30 is oxidized so as to be about 7 nm of its thickness. Thereafter, although not illustrated, impurity implantation for forming a well region and for forming a channel are applied to predetermined positions of the silicon substrate 11 and the epitaxial silicon region 30 by a lithography method and an ion implantation method, respectively. After the impurity implantation by the implantation method, activation processing for the implanted impurity is carried out by a well RTA method, the silicon oxide film formed already is removed, and thereafter, a gate oxide film (not shown) of about 7 nm is formed on the surface of the epitaxial silicon region 30 again. Note that, it is possible to apply ion implantation processing and activation annealing processing onto predetermined positions on the silicon substrate 11 before the epitaxial silicon region 30 is formed.

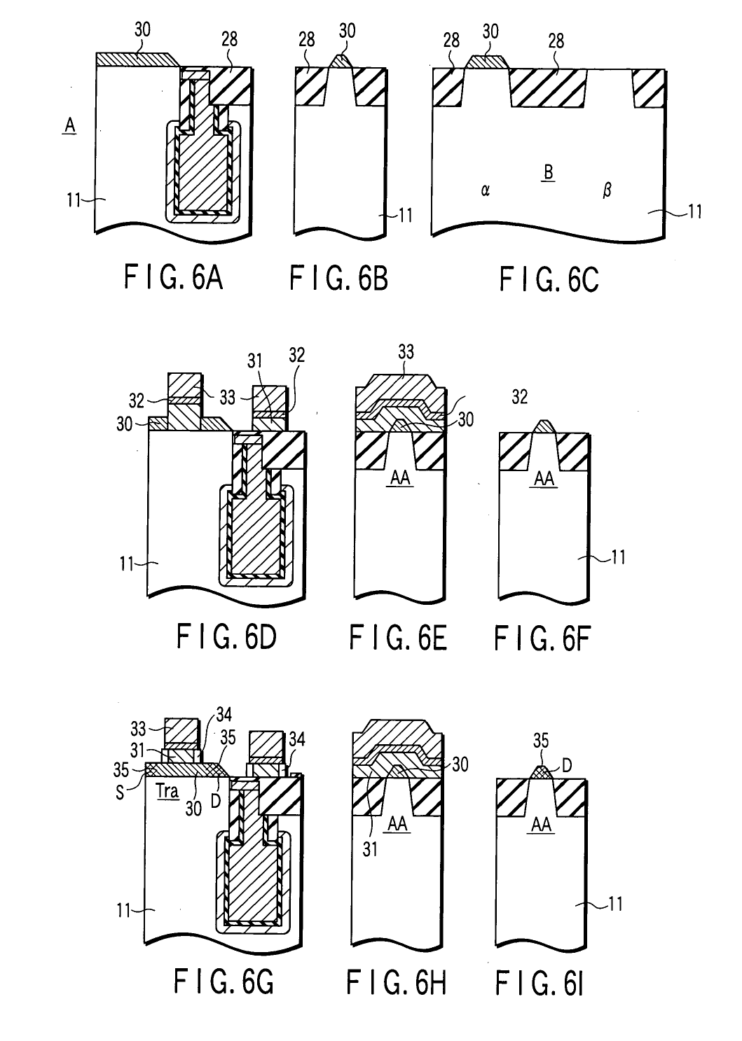

At that time, as shown in FIGS. 6A, 6B, and 6C, the surfaces of the STI oxide films 28 are etched back to some extent by pretreatment for oxidization or the like. However, it is necessary to optimize an STI etching-back amount and a pretreatment amount such that the levels of the surfaces of the STI oxide films 28 are not made to be finally the original level or less of the surface of the silicon substrate 11. Here, the case is shown in which the surfaces of the STI oxide films 28 are made to be exactly the same level as the surface of the silicon substrate 11.

As shown in FIGS. 6D and 6E, after the gate oxide film (not shown) is formed, for example, a polysilicon film 31 for gate electrode of about 80 nm, a WSi film 32 of about 550 nm, and a cap SiN film 33 of about 200 nm are deposited on the entire surface of the silicon substrate 11. Then, a GC (gate contact) resist pattern is formed by the lithography method, and the SiN film 33 is etched by RIE. Thereafter, a pattern of a gate contact portion is formed by removing the resist, and etching the WSi film 32 and the polysilicon film 31 by using the cap SiN film 33 as a mask.

Next, as shown in FIG. 6G, a gate side wall oxide film 34 is formed so as to have a thickness of about 10 nm by being oxidized by a thermal oxidation method. At that time, although not illustrated, an oxide film is formed also on the exposed surface of the silicon substrate 11. Thereafter, LDD diffusion layers 35 for the source S and drain D are formed. The LDD regions of the source S and drain D are formed by forming a resist pattern for ion implantation by the lithography method, and by implanting P or As ions into the source S and drain D forming regions at the both sides of the channel of the cell transistor Tra in the epitaxial silicon region 30 by the ion implantation method using the pattern. At the same time, LDD diffusion layers for the source S and drain D are formed as needed on the epitaxial silicon region 30 for forming a transistor on the peripheral circuit section B shown in FIG. 6C. Thereafter, activation of the diffusion layers is carried out by annealing the entire surface.

Moreover, as shown in FIGS. 7A, 7B, and 7C, an SiN film is deposited on the entire surface, anisotropic etching by RIE is applied thereto, and spacer SiN films 36 are formed at the outer sides of the gate side wall oxide films 34. Thereafter, ion implantation for the source and drain are further carried out, and annealing for activation are carried out, which forms the memory transistor Tra.

Thereafter, as shown in FIGS. 7D, 7E, and 7F, a barrier SiN film 37 is deposited on the entire surface so as to have a thickness of 8 nm, and a BPSG film 38 is deposited so as to have a thickness of 400 nm as an interlayer insulation film thereon. At that time, annealing, for example, at 750° C. and for about 15 minutes is applied thereto in order to reduce defects caused by defects in burying an interlayer film such as a CB short defect at the post-process. Thereafter, the surface of the BPSG film 38 is flattened by CMP, and a plasma TEOS film 39 is deposited so as to be about 60 nm on the entire surface on the surface of the BPSG film 38.

Subsequently, as shown in FIGS. 7G and 7I, a resist pattern is formed by the lithography method in order to form an opening portion 40 at the upper portion of the storage node section 23 of the capacitor Ct. The plasma TEOS film 39 and the BPSG film 38 at positions corresponding to the opening portion 40 are removed by etching with the pattern as a mask, and the barrier SiN film 37 is exposed at the bottom portion thereof.

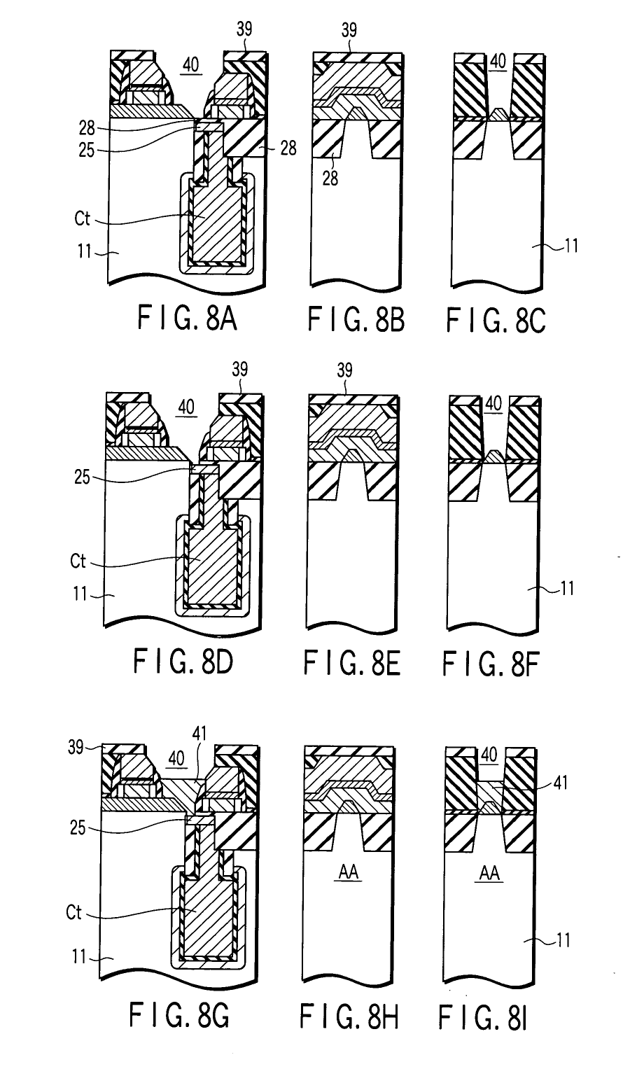

Next, as shown in FIG. 8A, a part of the oxide film 28 remaining at the process of FIG. 6A is exposed at the top portion of the trench of the capacitor Ct by removing the exposed barrier SiN film 37, and in FIG. 8D, the exposed oxide film 28 is removed by etching, and a storage node poly-silicon film 25 under the oxide film is exposed.

In this state, as shown in FIGS. 8G, 8H, and 8I, an aSi film 41 doped with P ions is deposited so as to be about 220 nm on the entire surface, and is etched back up to having a thickness of about 150 nm from the plane of the substrate 11 in the opening portion 40 so as to have a desired depth from the plane of the silicon substrate 11, which forms a surface strap SS for a source contact 41.

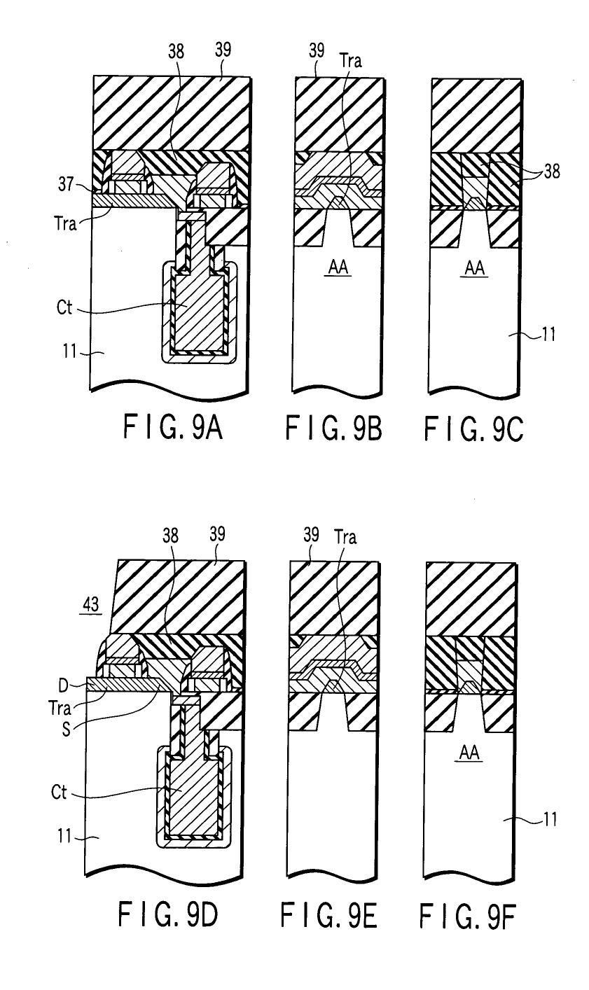

Moreover, as shown in FIGS. 9A, 9B, and 9C, the opening portion 40 is filled by depositing the BPSG film 38 again, and annealing for a reflowed portion is carried out. Then, after the surface is flattened by CMP, the plasma TEOS film 39 for an interlayer insulation film is deposited so as to have a thickness of 600 nm, and the layer density is unified by annealing.

Thereafter, as shown in FIG. 9D, a resist pattern is formed by the lithography method in order to form a bit line contact at the drain side of the memory transistor Tra, and the plasma TEOS film 39 and the BPSG film 38 are removed by etching with the resist as a mask. Thereby, the contact hole 43 is formed. After the contact hole 43 is formed, the resist is removed, the barrier SiN film 37 exposed at the bottom portion of the contact hole 43 as well is removed by etching, and the drain region D of the memory transistor Tra is exposed at that portion.

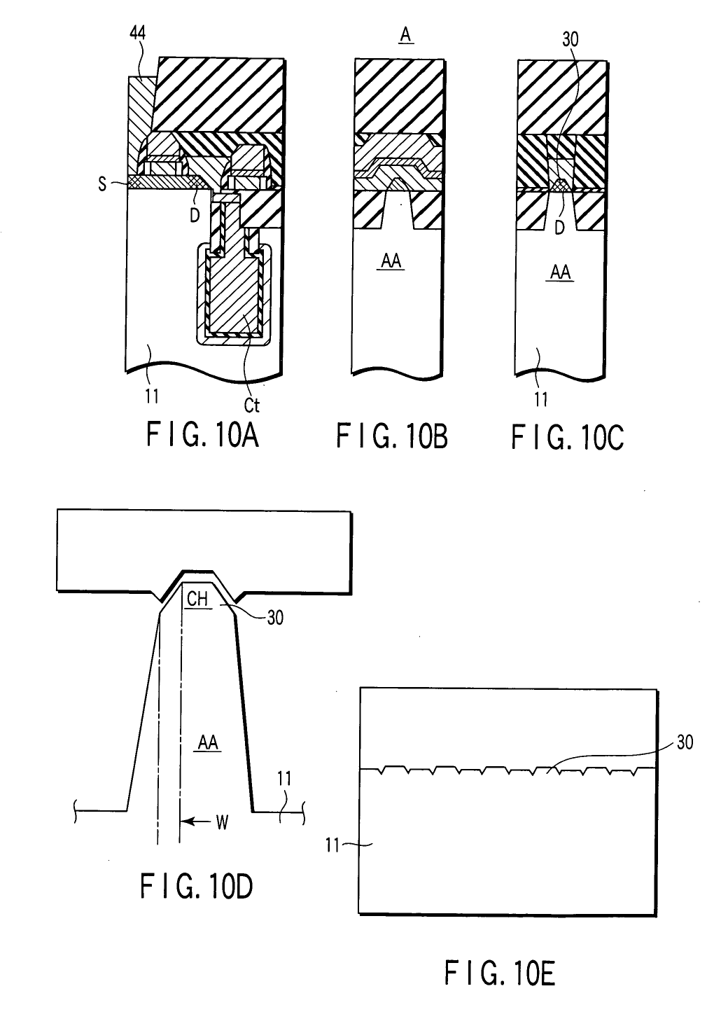

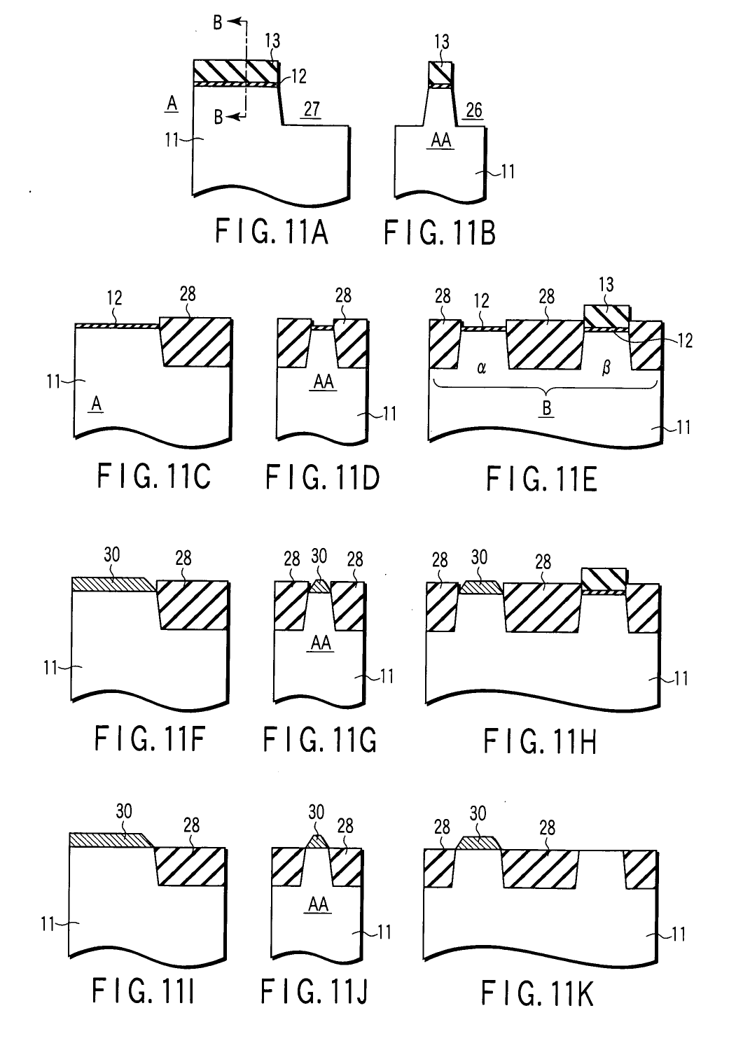

In this state, as shown in FIG. 10A, aSi on which P ions have been doped is deposited on the entire surface, and a bit contact 44 is formed by carrying out etch-back up to a position sinking down, for example, about 150 nm from the upper plane of the plasma TEOS film 39.

Subsequently, as shown in FIGS. 1D and 1E, as needed, a contact hole for forming, for example, the contact 45 of the gate of the transistor Trb of the peripheral circuit section B is formed in advance by the lithography method and RIE method thereafter.

At the last, as shown in FIGS. 1A to 1C, a resist pattern for forming a bit line opening for burying a bit line 46 is formed by the lithography method. A trench of about 200 nm is formed by etching the plasma TEOS film 39 which is an interlayer insulation film with the resist pattern as a mask. Thereafter, a Ti/TiN film of a barrier metal is deposited in the trench by a spattering method, and W is further buried thereon. An unwanted part of the buried W is removed so as to be flattened by CMP, which forms the bit line 46. At that time, a continuous wiring trench is formed in the opened contact hole on the peripheral circuit section B as well, and the wiring of the peripheral circuit section B is also simultaneously formed with W buried thereon.

The process of forming one wiring layer on the memory section A including the memory transistor Tra and the capacitor Ct, and the peripheral circuit section B is described by referring to FIGS. 1A to 10E. However, an actual DRAM chip has a wiring layer having a plurality of layers on the silicon substrate 11, and a DRAM chip having a multi-layer wiring layer is completed through a similar process.

FIG. 10D is an enlarged view showing the area AA portion in FIG. 10C, and FIG. 10E shows an SEM photograph image obtained by photographing the portion of the epitaxial silicon region 30 formed on the actual silicon substrate 11. As clear from FIG. 10D, a channel CH is formed so as to continue on the inclined planes and all over the top flat surface of the silicon region 30.

With respect to the memory transistor Tra in the present embodiment described above, when the epitaxial silicon region 30 formed by the selective epitaxial growth method on the AA region is formed, the width of the area AA region is provided so as to be a predetermined dimension, i.e., the top portion width is provided so as to be 60 nm or less, and the included angle of 120° or more and 148° or less is formed at the convex top portion region. Thus, it is possible to make the channel width long and the drivability great while the miniaturization thereof is realized, and the punch through deterrence and the cutoff characteristic can be improved. Accordingly, by using the memory transistor in the memory cells, a semiconductor memory device such as a DRAM which has a large capacity and a good characteristic, and a method of manufacturing the same can be provided.

### Second Embodiment

Hereinafter, manufacturing processes of the second embodiment according to the present invention and a semiconductor memory device manufactured through the processes will be described by referring to FIGS. 11A to 13C. In the following description, portions which are the same as or similar to those of the first embodiment are denoted by the same or similar reference numerals, and detailed descriptions thereof will be omitted.

As shown in FIGS. 11A and 11B, the SiO₂ film 12 and the SiN film 13 are successively formed on the surface of the memory cell A of the silicon substrate 11 in the same way as in the first embodiment. After a resist film is deposited, a resist pattern for the area AA is formed by the lithography method, and the SiN film 13 and the SiO₂ film 12 are successively etched by using the resist as a mask. Consequently, the STI groove 26 shown in FIG. 11B is formed in a longitudinal direction of the area AA, and the STI groove 27 shown in FIG. 11A is formed in a direction perpendicular thereto. Note that FIG. 11B is a cross sectional view taken along line B-B of FIG. 11A and seen in the direction of the arrow.

Next, as shown in FIGS. 11C, 11D, and 11E, the AA portion formed at the memory cell section A, i.e., the side walls of the STI grooves 26 and 27 are oxidized by the thermal oxidation method, and for example, an oxide film (not shown) of about 10 nm is formed. Thereafter, the STI grooves 26 and 27 are filled with the oxide film 28 by an HDP method or the like, and the device is polished until the SiN film 13 is made to remain to have a predetermined thickness by the CMP method so as to be flattened. Next, the oxide film 28 is etched back such that the surface thereof comes about 30 nm above from the surface of the substrate 11 by wet etching, and then, the remaining SiN film 13 is removed. In this way, the STI oxide film 28 is formed. At that time, as shown in FIG. 11E, the SiN film 13 may be removed, as the α section, on the peripheral circuit section B in the same way as in the cell section A. Or, a region on which the SiN film 13 is made to remain, as the β section, may be formed by etching the SiN film 13 in a state of being covered with the resist mask. As the α section and the β section, a region from which the SiN film 13 has been removed and a region on which the SiN film 13 has been made to remain may be mixed.

Next, as shown in FIGS. 11F, 11G, and 11H, after the SiO₂ film 12 on the silicon film 11 is removed, the epitaxial region 30 is formed on the exposed surface of the silicon substrate 11 by the selective epitaxial growth method. At this time, the epitaxial region 30 is made in a trapezoidal shape having inclined planes reflecting the crystal surface orientation of silicon. At this time, the epitaxial region 30 is formed on the entire surface region of the silicon substrate 11 from which the SiN film 13 on the memory cell section A of the DRAM and the peripheral circuit section B has been removed. Note that the SiN film 13 made to remain on the P section of the peripheral circuit section B is removed after the region 30 is formed.

Next, as shown in FIGS. 11I, 11J, and 11K, the surface of the epitaxial region 30 is oxidized so as to be about 7 nm, the lithography method followed by the ion implantation method are carried out, and a desired well region and a desired channel region are formed at desired positions. After the process of ion implantation, activation of the implanted impurity is carried out by a well RTA method. Then, the oxide film formed on the surface of the epitaxial region 30 is removed, and a gate oxide film (not shown) is formed so as to be about 7 nm on the surface of the exposed silicon. Although the STI oxide films 28 are etched back by pretreatment of oxidation or the like, it is necessary to optimize an STI etching-back amount and a pretreatment amount such that the STI oxide films 28 are finally not made lower than the original surface of the silicon substrate 11.

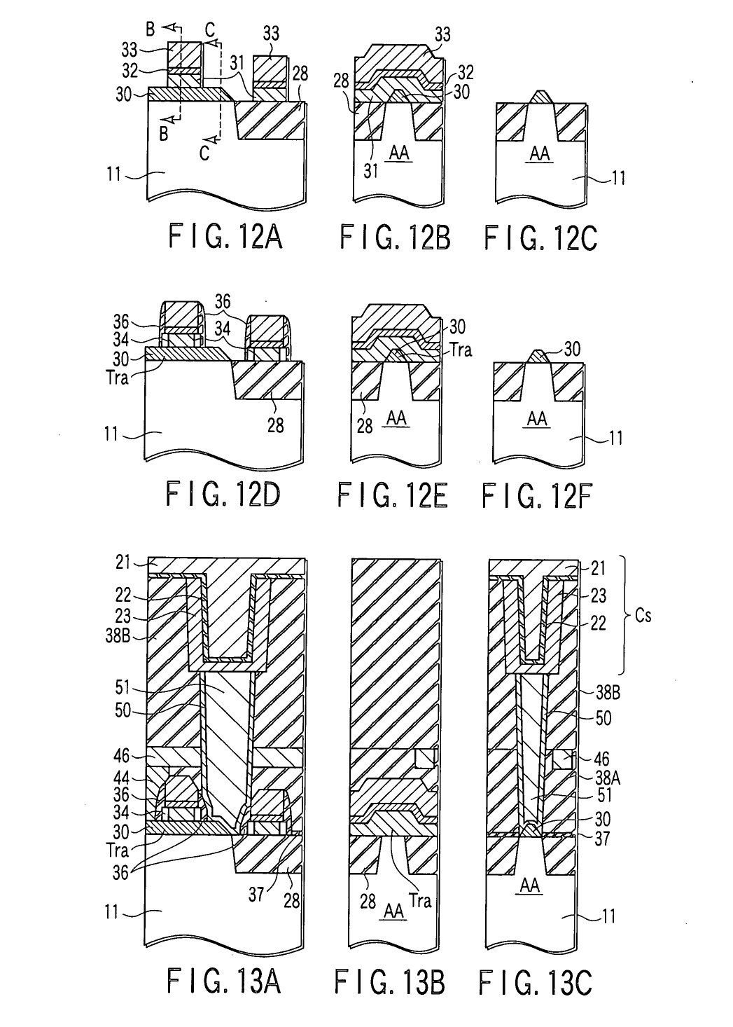

After the gate oxide film (not shown) is formed, as shown in FIGS. 12A, 12B, and 12C, for example, the polysilicon film 31 for gate electrode of about 80 nm, the WSi film 32 of about 550 nm, and the cap SiN film 33 of about 200 nm are deposited on the entire surface of the silicon substrate 11. Then, a GC resist pattern is formed by the lithography method, and the SiN film 33 is etched by the RIE method. Thereafter, a pattern on the gate contact portion is formed by removing the resist, and by etching the WSi film 32 and the polysilicon film 31 by use of the cap SiN film 33 as a mask. Here, FIG. 12B is a cross sectional view taken along line B-B in the FIG. 12A and seen in the direction of the arrows, and FIG. 12C is a cross sectional view, in the same way, taken along lines C-C and seen in the direction of the arrow.

Next, as shown in FIGS. 12D, 12E, and 12F, in the same way as in the first embodiment, the gate side wall oxide film 34 is formed so as to have a thickness of about 10 nm by being oxidized by the thermal oxidation method. At that time, although not illustrated, an oxide film is simultaneously formed on the exposed surface of the silicon substrate 11. Thereafter, LDD diffusion layers for the source/drain are formed. The LDD regions for the source and drain are formed by forming a resist pattern for ion implantation by the lithography method, and by implanting P or As ions into the source/drain forming regions at the both sides of the channel of the cell transistor Tra of the epitaxial silicon region 30 by the ion implantation method using the pattern. At the same time, in the same way as shown in FIG. 6C, LDD diffusion layers for the source/drain are formed as needed on the epitaxial silicon region for forming transistor on the peripheral circuit section as well. Thereafter, activation of the diffusion layers is carried out by annealing the entire surface.

Moreover, an SiN film is deposited on the entire surface to apply anisotropic etching by means of the RIE thereto, and the spacer SiN films 36 are formed at the outer sides of the gate side wall oxide film 34. Then, ion implantation for the source and drain is further carried out, and annealing for activation is applied thereto, which forms the memory transistor Tra.

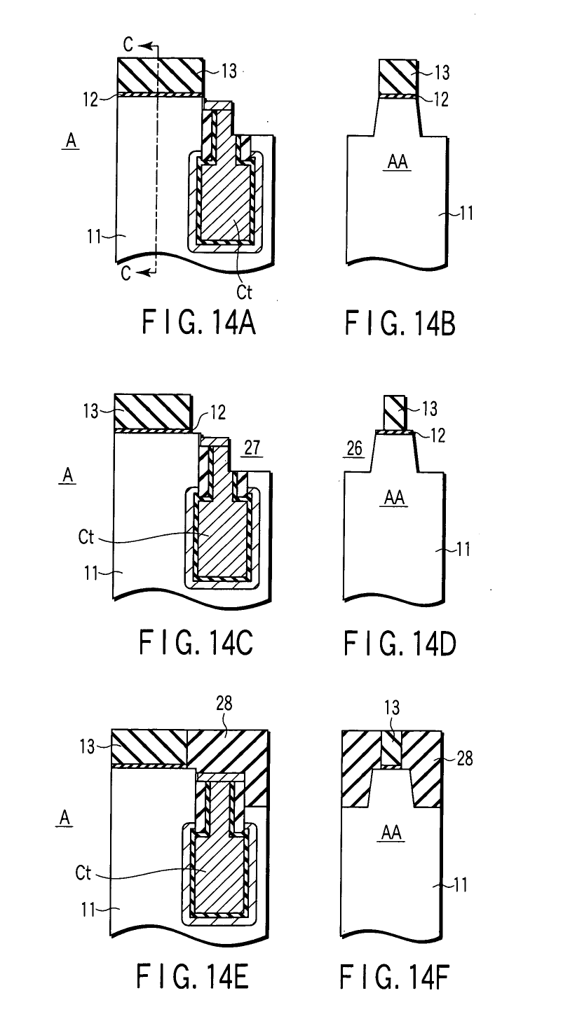

Subsequently, as shown in FIGS. 13A, 13B, and 13C, the barrier SiN film 37 is deposited so as to have a thickness of 8 nm, and a BPSG film 38A is deposited so as to have a predetermined thickness as an interlayer insulation film on the barrier SiN film 37. At that time, as needed, annealing, for example, at 750° C. and for about 15 minutes is carried out in order to improve the performance in burying W wiring or the like at the post-process.

Further, in the same way as shown in FIGS. 9 and 10, the contact 44 connected to the drain of the memory transistor Tra is formed, and moreover, the W bit line 46 is buried to be formed on the surface of the BPSG film 38A.

Moreover, another BPSG film 38B is deposited so as to have a predetermined thickness on the BPSG film 38A in order to form a stack capacitor Cs above the source of the memory transistor Tra, and the BPSG films 38B and 38A are etched by the lithography method. As a consequence, a storage node contact hole for connecting the storage node 23 of the stack capacitor Cs to the source of the transistor Tra is formed, and a storage node contact 51 is formed by burying W into the inner wall of the contact hole via a barrier layer 50.

A trench for forming the stack capacitor Cs is formed by etching back the buried W film of the storage node contact 51 up to a predetermined depth. The storage node 23 is formed in the trench, a capacitor dielectric film 22 such an NO film is formed on the inner wall thereof, and moreover, the inner space is buried with a capacitor electrode film 21, which forms the stack capacitor Cs. In this way, a stack DRAM chip of the second embodiment is manufactured.

In accordance with the second embodiment, as shown in FIG. 13, the stack capacitor Cs is formed after the memory cell transistor Tra is formed on the epitaxial silicon region 30. Therefore, as compared with the case in which the trench capacitor is formed in the silicon substrate 11, the effects that the process is made comparatively easier, the insulation performance of the capacitor can be sufficiently ensured, and the capacity of the capacitor can be taken in a large scale, or the like can be obtained.

### Third Embodiment

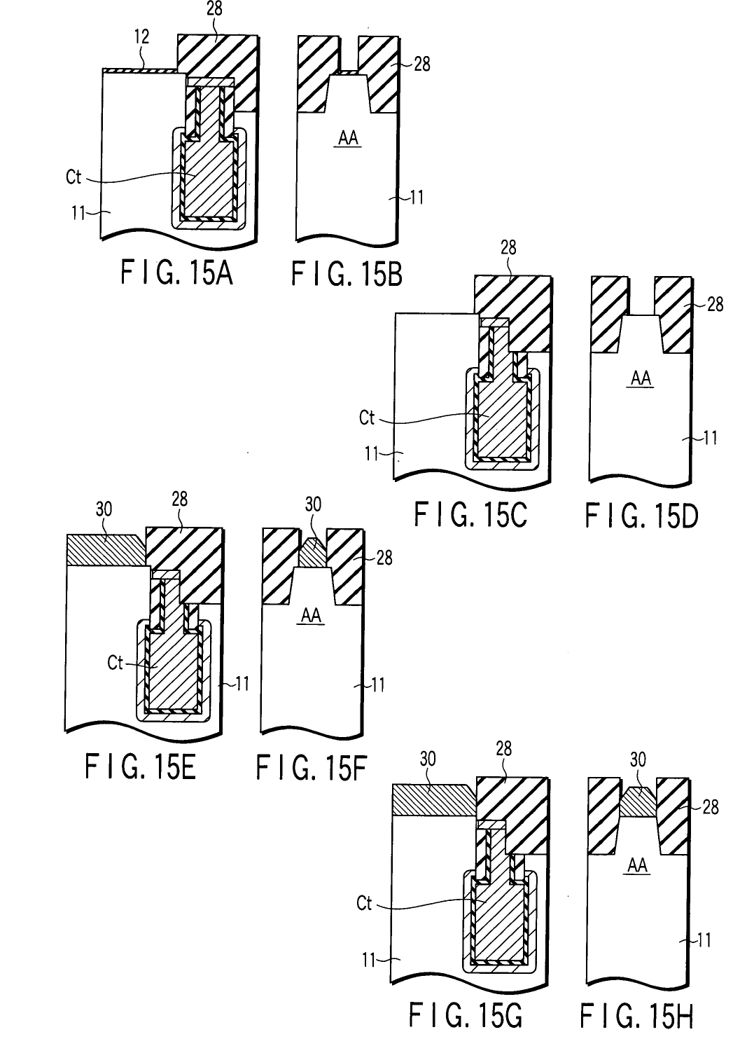

Hereinafter, a structure according to a third embodiment of the present invention and a method of manufacturing the same will be described by referring to FIGS. 14A to 15H. In the following description as well, portions which are the same as or similar to those of the first and second embodiments are denoted by the same or similar reference numerals, and detailed descriptions thereof will be omitted.

FIG. 14A is a cross sectional view in a state in which the trench capacitor Ct is formed at the memory cell section A, and FIG. 14B is a cross sectional view taken along line B-B thereof and seen in the direction of the arrows. Up to this process, the device is formed in the same way as in the processes from FIG. 1A to FIGS. 5B and 5C of the first embodiment.

In this state, as shown in FIGS. 14C and 14D, the SiN film 13 is etched by hot phosphoric acid or the like, and the side surfaces of the SiN film 13 are backed up by a predetermined amount from the STI edge portion as illustrated, and the surface of the SiO₂ film 12 is slightly exposed. This backed-up amount is appropriately set usually within a range of 10 nm to 30 nm in accordance with a condition such as peeling-off of the SiO₂ film 12 thereafter, pretreatment of a selective epitaxial growth of silicon, or the like.

Next, as shown in FIGS. 14E and 14F, an oxide film (not shown) is formed by a thermal oxidation onto the AA side walls, and thereafter, the STI grooves 26 and 27 are filled with the STI oxide film 28 by an HDP or the like. Moreover, the STI oxide films 28 are flattened so as to reach the upper plane of the SiN film 13 by the CMP method.

Thereafter, as shown in FIGS. 15A and 15B, the SiN film 13 is removed, and the SiO₂ film 12 is exposed.

Moreover, as shown in FIGS. 15C and 15D, the exposed SiO₂ film 12 is removed by wet etching, the surface of the silicon substrate 11 is exposed, and pretreatment for forming a silicon region is applied thereto by the selective epitaxial growth method. At that time, the side walls of the STI oxide films 28 as well are backed up. However, it is necessary to strictly set a backed-up process amount of the SiN film 12 such that the STI oxide film 28 does not extend over the width of the AA.

Next, as shown in FIGS. 15E and 15F, the silicon region 30 is grown on the surface of the exposed silicon substrate 11 by the selective epitaxial growth method. At that time, a level of the silicon region 30 is freely set unless the level of the silicon region 30 is not over the level of the STI oxide films 28. Here, the side surfaces of the epitaxial silicon region 30 are stipulated by the side surfaces of the STI oxide films 28, and the upper portions thereof are made to be the side surfaces inclined in trapezoidal shapes reflecting the crystal surface orientation of silicon.

In FIGS. 15E and 15F, steps are formed on the STI oxide films 28 at the edge portion of the upper surface of the area AA. However, by adding the backed-up amount of the SiN film 13 and the wet etching amount of the pretreatment for peeling-off and the epitaxial growth of the SiO₂ film 12, the device can be formed such that steps are hardly formed on the STI oxide films 28 at the edge portion of the upper plane of the area AA, as shown in FIGS. 15G and 15H. This makes it possible to extend the channel width of the memory cell transistor up to the width of the area AA. Further, these processes are, as described in the first embodiment, the silicon epitaxial region 30 can be selectively formed by selectively making the SiN film 13 remaining at the peripheral circuit section.

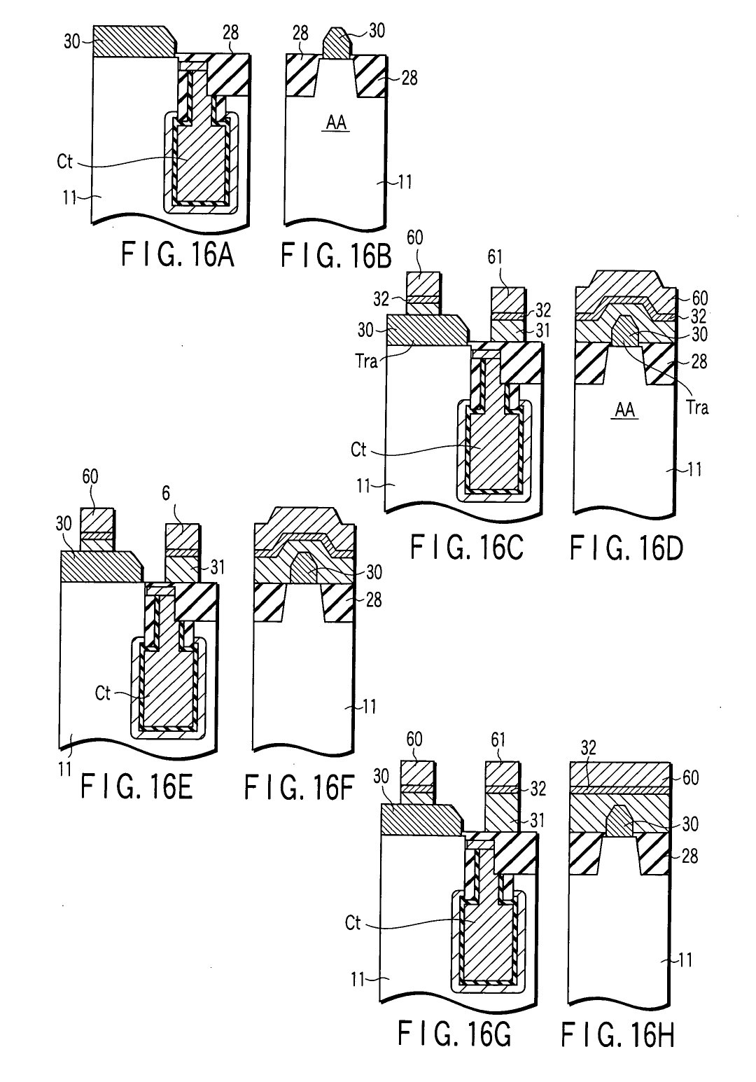

Next, as shown in FIGS. 16A and 16B, the STI oxide films 28 are etched back up to a desired level by wet etching. Here, the level is set at a position slightly higher than the surface of the silicon substrate 11. At that time, the upper planes of the STI oxide films 28 are set to be higher, for example, by about 50 nm than the upper plane of the epitaxial silicon region 30. Note that, although not illustrated, when a region on which an epitaxial region will be not formed by making the SiN film remain on the peripheral circuit section is formed, the remaining SiN is removed by hot phosphoric acid or the like after the STI oxide films 28 are etched back.

Thereafter, in the same way as in the first embodiment shown in FIGS. 6A to 7I, after an gate oxide film (not shown) is formed, the polysilicon film 31 for gate electrode, the WSi film 32, and the cap SiN film 33 are deposited on the entire surface of the silicon substrate 11. Then, a GC resist pattern is formed by the lithography method, and the SiN film 33 is etched by the RIE method. Thereafter, patterns on gate contact portions are formed by removing the resist, and etching the WSi film 32 and the polysilicon film 31 with the cap SiN film 33 being as a mask.

Subsequently, the source and drain are formed by forming a resist pattern for ion implantation by the lithography method, and by implanting P or As ions into the source/drain forming regions at the both sides of the channel of the cell transistor Tra of the epitaxial silicon region 30 by the ion implantation method using the pattern. At this time, at the same time, diffusion layers for the source/drain are formed as needed on the epitaxial silicon region for forming transistor on the peripheral circuit section. Thereafter, activation of the diffusion layers is carried out. Thereafter, activation of the diffusion layers is carried out by annealing the entire surface, and the memory transistor Tra is formed.

Accordingly, a gate electrode 60 which is an active W/L is formed on the memory transistor Tra, and a passing W/L 61 is formed on the trench capacitor Ct.

Here, there is a case in which, at the time of etching back the STI oxide films 28 after the epitaxial region 30 is formed, the STI oxide films 28 are etched back such that the surfaces of the STI oxide films 28 are made lower than the surface of the silicon substrate 11. In this case, the corners of the upper plane of the area AA are exposed so as to be those shown in FIGS. 16E and 16F after processing the gate electrode, but there is no problem in that case.

Further, when the epitaxial region 30 is higher, the levels of the active W/L 60 and the passing W/L 61 are different from each other, as shown in FIGS. 16C and 16D. However, the polysilicon layer for gate electrode 31 is deposited so as to be thick, and is flattened so as to get the levels lined up by the CMP or the like, and thereafter, the WSi film 32 and the cap SiN may be deposited, and the gate electrode may be processed. The case in which the device is formed in this way is shown in FIGS. 16G and 16H, in which the levels of the active W/L 60 and the passing W/L 61 are the same.

Thereafter, the processes until the trench capacitor type DRAM chip is completed are substantially the same as those in the first embodiment described above, and descriptions thereof will be omitted.

In the third embodiment, the SEG region 30 is made high as an FIN type FET, and is a shape having an included angle, which can provide the effect an electric current is further increased as compared with the first embodiment.

### Fourth Embodiment

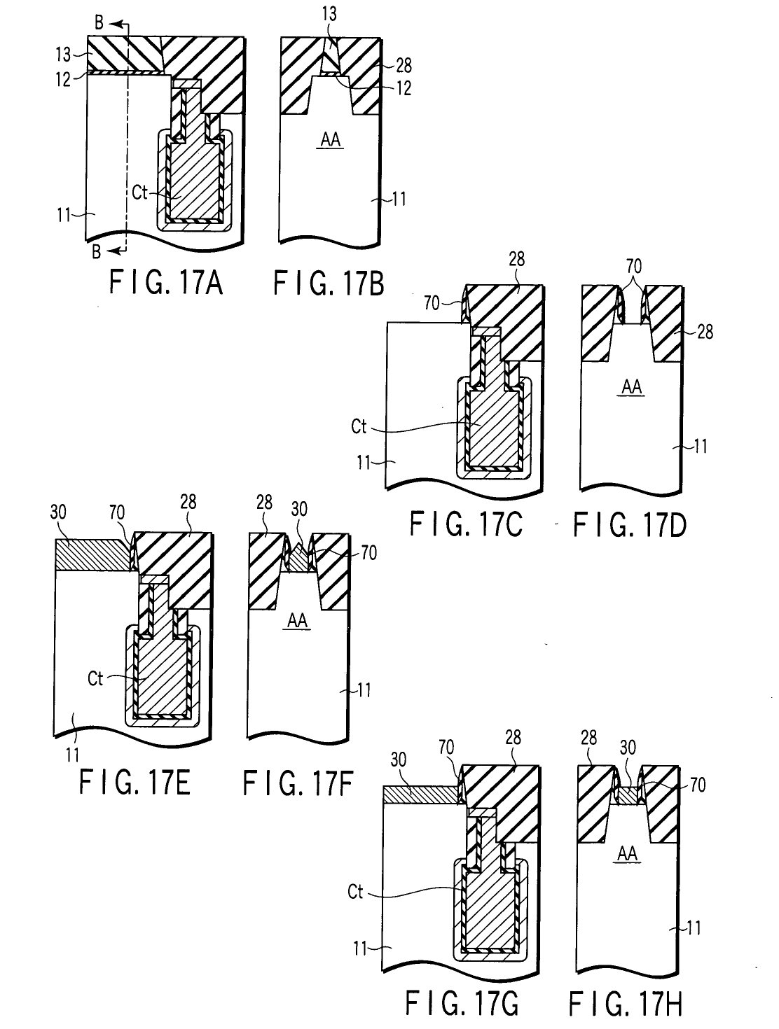

FIGS. 17A and 17B correspond to FIGS. 14E and 14F, and are formed thus far in the same way as in the third embodiment. However, in the third embodiment, the width of the lower surface and the width of the upper surface of the SiN film 13 are the same on the AA region. However, as shown in FIG. 17B, the width of the upper surface of the SiN film 13 is made smaller than the width of the lower surface, and the side surfaces of the SiN film 13 are made to be tapered planes. The tapered planes can be formed by appropriately setting the condition of an RIE at the time of forming the SiN film 13. Before the STI oxide film 28 is formed, the side surfaces of the SiN film 13 are backed up by hot phosphoric acid, and then, an oxide film (not shown) is formed by oxidizing the side walls of the silicon at the area AA, and the STI grooves are filled with the STI oxide films 28 so as to flatten the surface thereof by the CMP to be finished in the state of FIGS. 17A and 17B.

Thereafter, as shown in FIGS. 17C and 17D, the SiN film 13 is removed, and then, the surface of the silicon substrate 11 is exposed by removing the SiO₂ film 12. At that time, the STI oxide films 28 are backed up by wet etching. However, it is necessary to set a condition at the time of removing the SiN film 13 and the SiO₂ film 12 such that the STI oxide films 28 are not backed up so as to be less than the width of the area AA. Subsequently, SiN is deposited so as to be, for example, about 15 nm on the entire surface, and spacers 70 are formed at the side walls of the STI oxide films 28 by carrying out anisotropic etching by RIE.

Next, pretreatment is applied onto the exposed surface of the silicon substrate 11 by a hydrofluoric acid cleaning agent, and as shown in FIGS. 17E and 17F, the epitaxial region 30 is formed thereon by the selective epitaxial growth (SEG) method of silicon. At this time, the side walls of the upper portion of the epitaxial region 30 to be formed are made inclined planes reflecting the crystal surface orientation of silicon. However, in relation between the width and the height or level of the area AA, the upper portion of the epitaxial region 30 is not made to be a trapezoidal shape as in the first to third embodiments described above thus far, but the top end portion can be formed so as to have an acute angle as shown in FIG. 17F. This is the same as in the first to third embodiments.

Further, when the SiN spacers 70 are formed, by appropriately selecting a condition of an epitaxial growth, as shown in FIGS. 17G and 17H, the flat plane can be formed at the top portion of the epitaxial region 30.

Note that, although not illustrated, when a region on which an epitaxial region will be not formed by making the SiN film remain on the peripheral circuit section is formed, the remaining SiN may be removed by hot phosphoric acid or the like after the STI oxide films 28 are etched back.

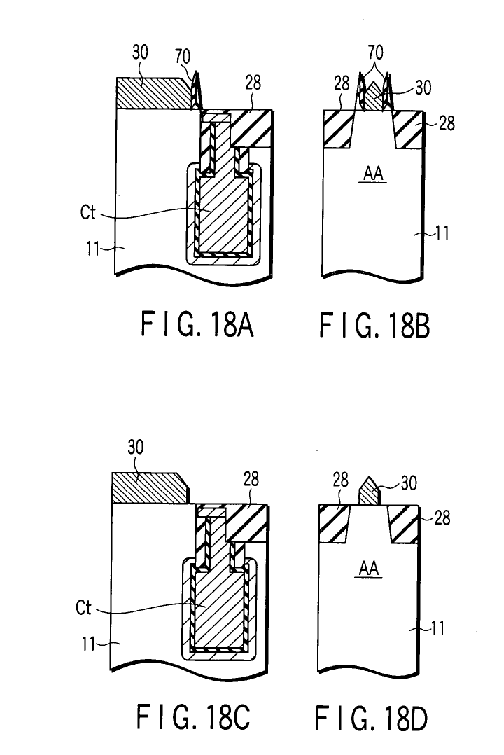

Subsequently, as shown in FIGS. 18A and 18B, the STI oxide films 28 are etched back by wet etching so as to have a desired level. Here, the upper planes of the STI oxide films 28 are the same as the plane of the silicon substrate 11.

Thereafter, as shown in FIGS. 18C and 18D, the spacers 70 are backed up by hot phosphoric acid. At that time, when a region on which an epitaxial region will be not formed is formed on a peripheral circuit section (not shown), i.e., when the SiN film is selectively made to remain, the SiN film can be removed at the same time when the spacers 70 are peeled off at the post-process.

Then, although not illustrated, a gate electrode is formed in the same way as in the third embodiment, and a DRAM chip in which the trench capacitor Ct is formed on the memory cell section A is completed by passing through the processes which are the same as those of the first embodiment.

In the fourth embodiment, the spacers 70 are used at the time of forming the epitaxial region 30, for example. Therefore, as compared with the case in the first embodiment, there is no backing of the side walls of the STI oxide films 28 by the processing before the epitaxial silicon region 30 is grown. In particular, a dimension in the AA width direction can be precisely set, and the width thereof can be further reduced, so that even if a memory cell transistor is miniaturized, the drivability thereof can be sufficiently ensured. Further, as clear from FIG. 18D, exact step portions are formed between the upper plane of the AA region and the bottom end portion of the epitaxial silicon region 30 after the spacers 70 are removed. Thus, it is easy to estimate the manufacturing processes from a DRAM which is a finished product.

Here, by making the top end portion of the epitaxial silicon region 30 which will be a channel of the memory cell transistor have an acute angle as shown in FIGS. 18B and 18D, it is possible to improve the performance of the transistor.

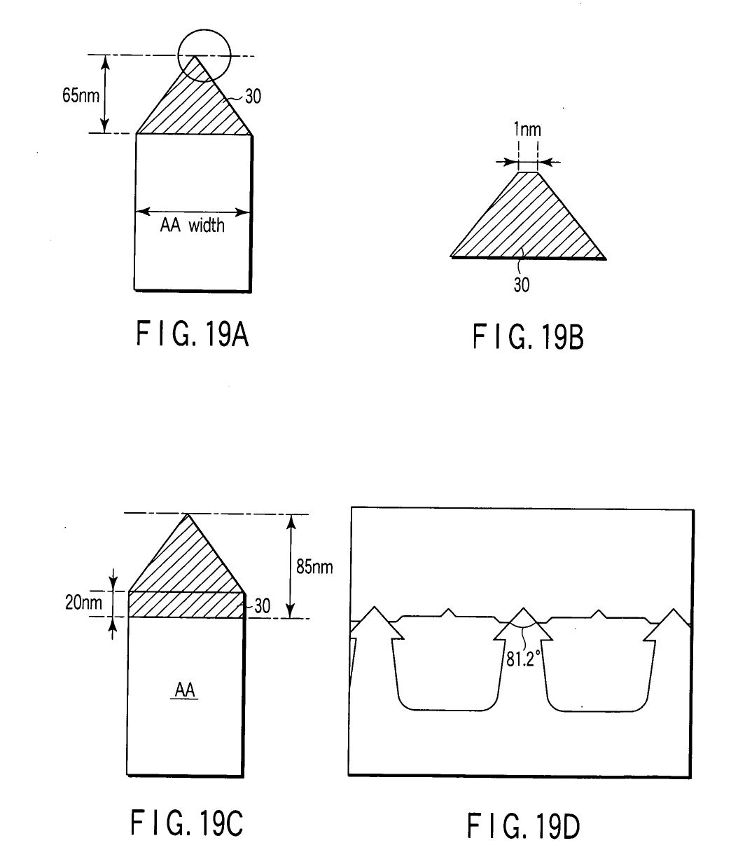

FIG. 19A shows an enlarged sectional view in which a shape of the cross section of the epitaxial silicon region 30 is formed in a triangle. FIG. 19C shows an enlarged sectional view in which a shape of the cross section of the epitaxial silicon region 30 is formed in a pentagon, for example, as in the embodiment of FIG. 15H. FIG. 19B is an enlarged view of the top end portion surrounded by the circle of FIG. 19A. Here, suppose that the top end of the region 30 is made sharp such that a maximum width of the top end portion thereof is about 1 nm as shown in FIG. 19B. Further, the level of the region 30 of FIG. 19A is set to 65 nm, the level of the region 30 of FIG. 19C is set to 85 nm, and the widths of the AA portion are respectively set to 110 nm and 80 nm. Further, the included angle of the region 30 is 80° when the AA width is 110 nm, and is 62.6° when the AA width is 80 nm. FIG. 19D is an SEM photograph example of an actual trial product in a case of the region 30 whose cross section is a pentagon (AA width is 110 nm), and the included angle is 81.2°.

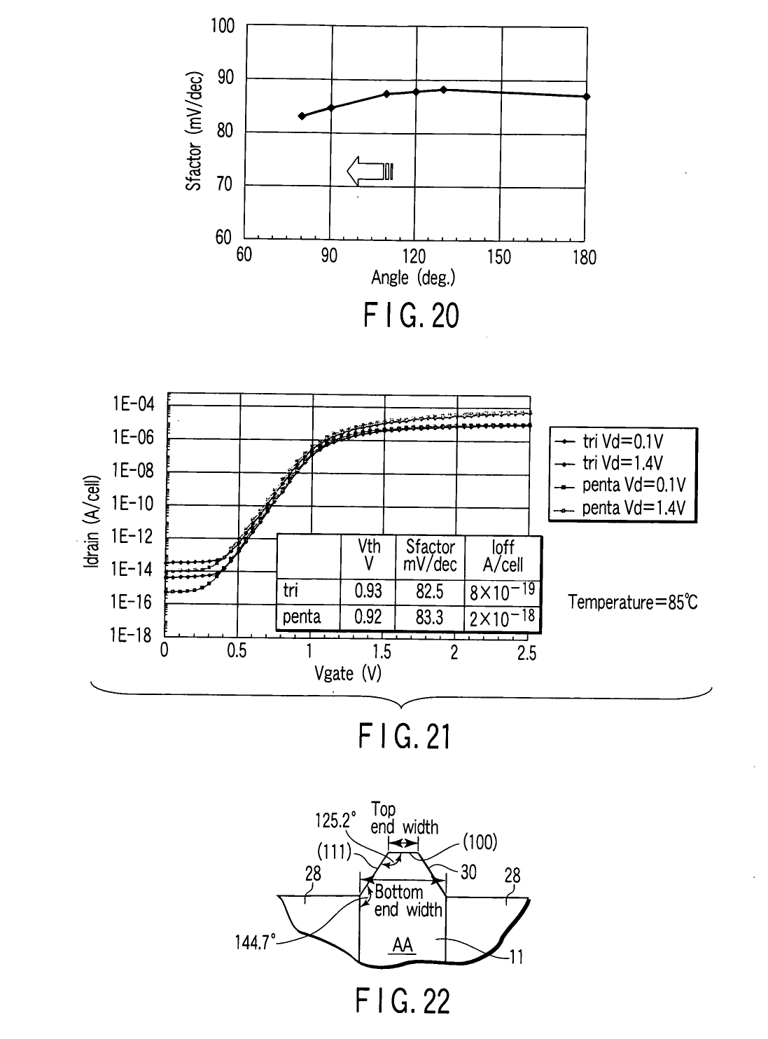

In this way, by making the top end of the epitaxial silicon region 30 sharp as a substantial triangle tip, a transistor having a small S factor as shown in FIG. 20 can be formed at the time of forming the memory cell transistor Tra. As a result of a simulation, this transistor is started to be turned on in advance at the acute angle portion of the top end of the region 30, and is made to have a characteristic that the channel extends downward in the AA portion direction as the gate voltage is raised up. However, the simulation results in such that an electric current density at the top corner portion is always high under any gate bias condition, and the top corner potion is made to be a main channel. As the characteristic of the transistor, the characteristic is determined at the upper portion of the channel, and is a characteristic having a sufficiently small S factor.

The top portions of the protruding portions 30 shown in FIGS. 1A to 1C, FIGS. 13A to 13C and FIGS. 16G and 16H may also be made as similar triangler shapes in the same manner as that shown in FIGS. 19A to 19C.

FIG. 21 shows data as a result of investigating the relationship between a gate voltage and a drain current of the formed transistor in a case of a triangle of the cross section in FIG. 19A (tri in the drawing) and a case of a pentagon of the cross section in FIG. 19C (penta in the drawing). Here, the AA width is 110 nm.

Next, the results in which the relationship between the top end width and the bottom end width of the epitaxial silicon region and S factor is investigated, which are used in the respective embodiments of the invention, will be described.

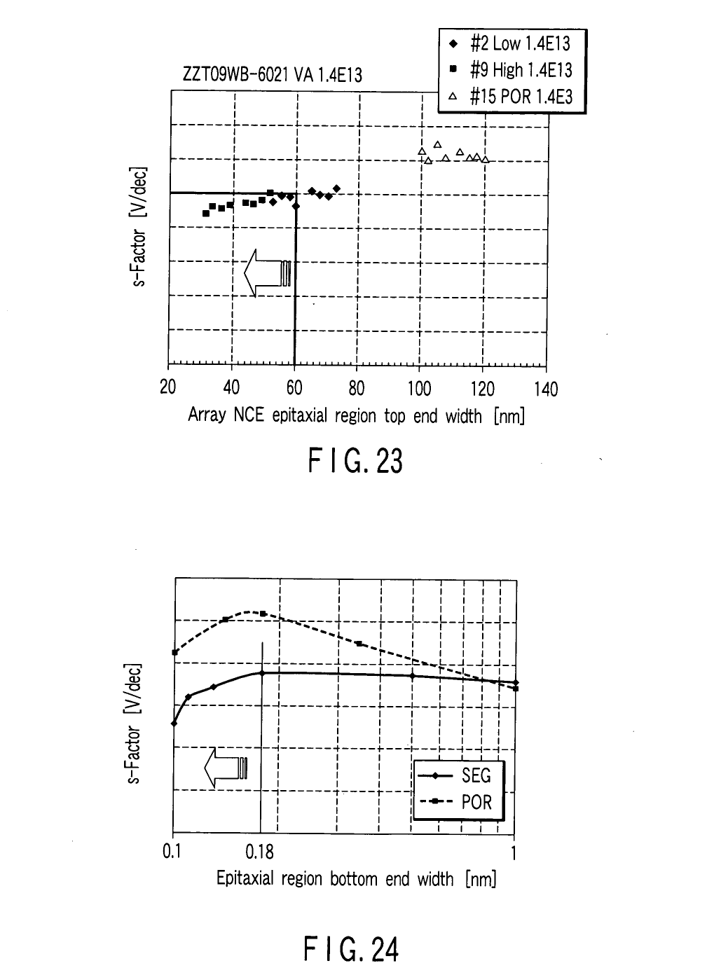

FIG. 22 shows the epitaxial silicon region (epi region) 30 formed on the AA portion provided between the STI oxide films 28 of the silicon substrate 11 so as to be enlarged. As a result of investigating the relationship between the top end width and the bottom end width thereof and S factor, the results are respectively shown as in FIGS. 23 and 24. As the epitaxial silicon region 30 in an example shown in FIG. 22, the trapezoidal shaped region 30 is used whose top end width is 60 nm and bottom end width is 180 nm, and in which the inclined planes formed between the top end and the bottom end of the region 30 are the (111) facets of silicon, and the top end plane is a (100) facet in parallel with the silicon substrate, and angles formed by the side surfaces of the area AA and the (111) facets are 144. 7°, and angles formed by the (111) facets and the (100) facet are 125.2°.

Here, as shown in FIG. 22, the region 30 has the inclined planes formed which are two (111) facets, and an included angle formed by extending these two (111) inclined facets is an acute angle. However, this included angle is preferably 20° or more and less than 90°.

FIG. 23 shows the relationship between the top end width of the epitaxial silicon region 30 and S factor. As clear from the graph of sample 1 (#2Low) and sample 2 (#9High), in a case in which the top end width is set to be 60 nm or less in a transistor for DRAM whose miniaturization has progressed as compared with the conventional example (#15POR), an S factor is made to be, for example, 0.1 or less, which has brought about a favorable result. Note that, as the sample 1 used here, a sample when the level of the epitaxial silicon region 30 formed on the semiconductor substrate is low such as 65 nm as shown in, for example, FIG. 19A is used. As the sample 2, a sample when the level of the region 30 is comparatively higher, such as 85 nm, than the sample 1 as shown in FIG. 19C is used. Further, the (100) facet of the top end of the region 30 is a flat plane as shown in FIG. 22 at the time of being formed by an epitaxial grows method. However, the portions crossing the (111) facets are rounded by various causes by the following processes, and an area of the flat plane portion of the top end of the trapezoidal shape region 30 is reduced. The top end width in such a case may be defined as a distance between the two points at which the remaining (111) facets and the (100) facet extend and cross each other.

Further, from the same viewpoint, as compared with one conventional example (POR) in which there is a trend toward that, as the bottom end width of the epitaxial region is made smaller, an S factor becomes at large value, in a trial product (SEG) according to the invention, a sufficiently small S factor can be obtained even in a DRAM whose miniaturization has progressed. In particular, as clear from FIG. 24, an S factor is reduced when the bottom end width is 180 nm or less, and it is understood that a good characteristic can be obtained when the bottom end width is set to be 180 nm or less.

In this way, in an aspect of the present invention, it is understood that a transistor having a good characteristic when the width of the (100) facet of the upper plane of the epitaxial silicon region 30 which is in parallel with the substrate surface is 60 nm or less. Moreover, it is understood that the fact is an important factor that only the (111) facets are the inclined planes of the trapezoidal shape region 30, and a top plane adjacent thereto is the (100) facet.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A semiconductor device comprising:
a semiconductor substrate;
element isolating regions formed on the semiconductor substrate;
an element forming region provided between the element isolating regions on the semiconductor substrate, the element forming region having a protruding portion being a selective epitaxial growth silicon region formed on the semiconductor substrate;
a transistor having a channel formed in the protruding portion of the element forming region; and
a capacitor formed in the semiconductor substrate to configure a memory cell of a DRAM in association with the transistor, wherein
the protruding portion in the element forming region includes first and second inclined and opposed planes arranged along a channel width direction of the transistor, and an upper plane provided between the first and second inclined planes.

2. The semiconductor device according to claim 1, wherein the upper plane has a width of 60 nm or less in the channel width direction, and an included angle formed between two extended planes of the first and second inclined planes is an acute angle to form a top of the protruding portion as a triangular tip.

3. The semiconductor device according to claim 1, wherein the first and second inclined planes of the protruding portion at the selective epitaxial growth silicon region are respectively (111) facets, and the upper plane is a (100) facet.

4. The semiconductor device according to claim 1, wherein a width of a bottom end of the protruding portion in the channel width direction is 180 nm or less.

5. The semiconductor device according to claim 1, wherein the transistor has a gate structure formed on an upper portion of the protruding portion including the first and second inclined planes in the channel width direction.

6. The semiconductor device according to claim 1, wherein the capacitor is formed in a trench configured in the semiconductor substrate.

7. The semiconductor device according to claim 1, wherein the capacitor is formed in an interlayer insulating structure formed on the semiconductor substrate.

8. A semiconductor device comprising:
a semiconductor substrate;
element isolating regions formed on the semiconductor substrate;
an element forming region provided between the element isolating regions on the semiconductor substrate, the element forming region being an etching-formed region having a protruding portion in the semiconductor substrate;
a transistor having a channel formed in the protruding portion of the element forming region; and
a capacitor formed in the semiconductor substrate to configure a memory cell of a DRAM in association with the transistor, wherein
the protruding portion in the element forming region includes first and second inclined and opposed planes arranged along a channel width direction of the transistor, and an upper plane provided between the first and second inclined planes.

9. The semiconductor device according to claim 8, wherein the upper plane has a width of 60 nm or less in the channel width direction, and an included angle formed between two extended planes of the first and second inclined planes is an acute angle to form a top of the protruding portion as a triangular tip.

10. The semiconductor device according to claim 8, wherein the first and second inclined planes of the protruding portion formed by etching are respectively (111) facets, and the upper plane is a (100) facet.

11. The semiconductor device according to claim 8, wherein a width of a bottom end of the protruding portion in the channel width direction is 180 nm or less.

12. The semiconductor device according to claim 8, wherein the transistor has a gate structure formed on an upper portion of the protruding portion including the first and second inclined planes in the channel width direction.

13. The semiconductor device according to claim 8, wherein the capacitor is formed in a trench configured in the semiconductor substrate.

14. The semiconductor device according to claim 8, wherein the capacitor is formed in an interlayer insulating structure formed on the semiconductor substrate.

15. A semiconductor device comprising:
a semiconductor substrate;
element isolating regions formed on the semiconductor substrate;
an element forming region provided between the element isolating regions in the semiconductor substrate, the element forming region having a protruding portion formed on the semiconductor substrate;
a transistor having a channel formed in the protruding portion of the element forming region; and
a capacitor formed on the semiconductor substrate to configure a memory cell of a DRAM in association with the transistor, wherein
in the channel width direction of the element forming region, a width of the protruding portion is narrower than a width of the element forming region in the semiconductor substrate.

16. The semiconductor device according to claim 15, wherein the protruding portion is formed in a selective epitaxial growth silicon region formed on the semiconductor substrate.

17. The semiconductor device according to claim 16, wherein the first and second inclined planes of the protruding portion at the selective epitaxial growth silicon region are respectively (111) facets, and the upper plane is a (100) facet.

18. The semiconductor device according to claim 15, wherein a width of a bottom end of the protruding portion in the channel width direction is 180 nm or less.

19. The semiconductor device according to claim 15, wherein the transistor has a gate structure formed on an upper portion of the protruding portion including the first and second inclined planes in the channel width direction.

20. The semiconductor device according to claim 15, wherein the capacitor is formed in a trench formed in the semiconductor substrate.
